(19) United States
(12) Patent Application Publication
(10) Pub. No.: US 2024/0222280 A1
(43) Pub. Date: Jul. 4, 2024

(54) SEMICONDUCTOR PACKAGES AND METHOD FOR FABRICATING THE SAME

(71) Applicant: Samsung Electronics Co., Ltd., Suwon-si (KR)

(72) Inventors: MyungDo CHO, Suwon-si (KR); Youngchan KO, Suwon-si (KR); Gyeongho KIM, Suwon-si (KR); Byung Ho KIM, Suwon-si (KR); Yongkoon LEE, Suwon-si (KR); Jeongho LEE, Suwon-si (KR)

(73) Assignee: Samsung Electronics Co., Ltd., Suwon-si (KR)

(21) Appl. No.: 18/363,995

(22) Filed: Aug. 2, 2023

(30) Foreign Application Priority Data
Dec. 29, 2022 (KR) 10-2022-0189162

(51) Int. Cl. H01L 23/538; H01L 21/48; H01L 21/56; H01L 23/00; H01L 23/31; H01L 23/498; H01L 25/065

(52) U.S. Cl. CPC H01L 23/5381; H01L 21/486; H01L 21/565; H01L 23/3128; H01L 23/49833; H01L 23/49866; H01L 23/5385; H01L 23/5386; H01L 24/16; H01L 25/0655; H01L 2224/16227; H01L 2224/16238; H01L 2924/182

(57) ABSTRACT

A semiconductor package may include: a first redistribution layer structure; a bridge structure on the first redistribution layer structure; a plurality of conductive pillars on the first redistribution layer structure and side by side with the bridge structure; an encapsulant molding the bridge structure and the plurality of conductive pillars on the first redistribution layer structure; a second redistribution layer structure on the encapsulant, wherein a region of the second redistribution layer structure on the bridge structure is defined as a first region and a region other than the first region is defined as a second region; and a plurality of bonding pads at the first region. A vertical thickness of the first region may be smaller than a vertical thickness of the second region.

### CROSS-REFERENCE TO RELATED APPLICATION

This application claims priority to and the benefit of Korean Patent Application No. 10-2022-0189162 filed in the Korean Intellectual Property Office on Dec. 29, 2022, the entire contents of which are incorporated herein by reference.

### BACKGROUND

### (a) Field

The present inventive concepts relate to semiconductor packages and methods for fabricating the same.

### (b) Description of the Related Art

A field of semiconductor packaging technology is gradually developing from a 2D package to a 2.5D package and from a 2.5D package to a 3D package. In the 2.5D package and the 3D package, may be desired to vertically stack semiconductor chips in a 3D stack, and the vertically arranged semiconductor chips are connected by a micro bump to which a fine process is applied.

The 3D stack of the semiconductor chips connected by the micro bump to which the fine process is applied may have to be electrically coupled to a semiconductor substrate in order to exchange a signal with other semiconductor chips. However, since the semiconductor substrate has a relatively large circuit line width when the semiconductor substrate is compared with the micro bump to which the fine process is applied, an intermediate medium capable of alleviating a difference in line width between the 3D stack using the micro bump and the semiconductor substrate having a large circuit line width is required in order to connect the 3D stack and the semiconductor substrate.

As such the intermediate medium, a silicon bridge applied with the fine process is well known. The silicon bridge is embedded in a semiconductor substrate, a redistribution layer (RDL) structure (an interposer) is formed on the semiconductor substrate in which the silicon bridge is embedded, and the 3D stack is mounted on the redistribution layer so that a connection structure between the silicon bridge and the 3D stack is formed.

Here, considering a pitch of adjacent terminals of the silicon bridge to which the fine process is applied, adjacent micro bonding pads formed at a redistribution layer structure may be required to have a pitch of 20 μm to 50 μm. However, it is difficult to form the micro bonding pads having the pitch of 20 μm to 50 μm on vias of the redistribution layer structure due to a limitation such as via size, via overlay, or the like of the redistribution layer structure.

In addition, in order to form micro bonding pads having the pitch of 20 μm to 50 μm on the vias of the redistribution layer structure, there is a problem in which a high resolution photo imagable dielectric (PID) may be required and new equipment may have to be introduced.

### SUMMARY

In some example embodiments, a new semiconductor package technology is provided in which the limitation such as the via size, the via overlay, or the like of the redistribution layer structure is not considered, a conventional material and conventional equipment are used, and/or a pitch between the micro bonding pads may be set to match a pitch of the terminals of the silicon bridge to which the fine process is applied.

In a semiconductor package according to some example embodiments, a via in an uppermost layer of a region of the redistribution layer structure disposed just above a silicon bridge may be deleted to overcome a limitation such as via size, via overlay, or the like of a redistribution layer structure and form micro bonding pads on the redistribution layer structure in consideration of a pitch of terminals of the silicon bridge to which a fine process is applied.

In a semiconductor package according to some example embodiments, a photoresist pattern forming a small-sized via at the uppermost layer of the region of the redistribution layer structure disposed just above the silicon bridge (e.g., vertically overlapping the silicon bridge) may be omitted (e.g., may be not formed), may include (e.g., may form) a photoresist pattern forming an entire surface opening at the uppermost layer of the region of the redistribution layer structure disposed just above the silicon bridge (e.g., vertically overlapping the silicon bridge) in order to solve a problem of a residue generated from a photoresist pattern when a small-sized via is formed, thereby improving the reliability of the resultant semiconductor package and any device including same based on omitting at least a portion of the photoresist pattern at a region of the redistribution layer structure vertically overlapping the silicon bridge and thus preventing residue generated from the photoresist pattern at the region based on forming a small-sized via therein.

In a semiconductor package according to some example embodiments an entire surface plating layer on copper pads may be included (e.g., may be formed) in order to reduce, minimize, or prevent a void due to consumption of copper (Cu) in the micro bonding pads.

A semiconductor package according to some example embodiments may include: a first redistribution layer structure; a bridge structure on the first redistribution layer structure; a plurality of conductive pillars on the first redistribution layer structure and side by side with the bridge structure; an encapsulant molding the bridge structure and the plurality of conductive pillars on the first redistribution layer structure; a second redistribution layer structure on the encapsulant, wherein a region of the second redistribution layer structure on the bridge structure is defined as a first region and a region other than the first region is defined as a second region; and a plurality of bonding pads at the first region. A vertical thickness of the first region may be smaller than a vertical thickness of the second region.

A semiconductor package according to some example embodiments may include: a first redistribution layer structure; a bridge structure on the first redistribution layer structure; a plurality of conductive pillars on the first redistribution layer structure and side by side with the bridge structure; a first encapsulant molding the bridge structure and the plurality of conductive pillars on the first redistribution layer structure; a second redistribution layer structure on the first encapsulant, wherein a region of the second redistribution layer structure on the bridge structure is defined as a first region and a region other than the first region is defined as a second region; and a plurality of first bonding pads at the first region; a plurality of second bonding pads on the second region; a first semiconductor chip and a second semiconductor chip on the plurality of first bonding pads and the plurality of second bonding pads; and a second encapsulant molding the plurality of first bonding pads, the plurality of second bonding pads, the first semiconductor chip, and the second semiconductor chip on the second redistribution layer structure. A vertical thickness of the first region may be smaller than a vertical thickness of the second region.

A method for manufacturing a semiconductor package according to some example embodiments may include: mounting a bridge structure on a first redistribution layer structure and forming a plurality of conductive pillars on the first redistribution layer structure; molding the bridge structure and the plurality of conductive pillars with an encapsulant; and forming a second redistribution layer structure on the encapsulant, wherein a region of the second redistribution layer structure on the bridge structure is defined as a first region and a region other than the first region is defined as a second region, and a vertical thickness of the first region is smaller than a vertical thickness of the second region.

According to some example embodiments, in the semiconductor package using (e.g., including) the silicon bridge, a problem of difficulty in forming the micro bonding pads on the redistribution layer structure due to a limitation such as a need for a high resolution photo imagable dielectric (PID), a need for new equipment, a lack of overlay margin, or the like may be solved through a structure change of the redistribution layer structure such as deleting the via from the uppermost layer of the region of the redistribution layer structure disposed just above (e.g., vertically overlapping) the silicon bridge.

According to some example embodiments, the small-sized via may not be formed at the uppermost layer of the region of the redistribution layer structure disposed just above the silicon bridge and the entire surface opening may be formed so that a problem of a residue generated when the small-sized via is formed is solved.

According to some example embodiments, the entire surface plating layer may be formed on a copper pad of a micro bonding pad so that formation of the void due to consumption of copper (Cu) in the micro bonding pads is reduced, minimized, or prevented.

### BRIEF DESCRIPTION OF THE DRAWINGS

FIG. 1 is a cross-sectional view illustrating a semiconductor package according to some example embodiments in which a second redistribution layer structure electrically coupling a bridge structure and a first semiconductor chip and the bridge structure and a second semiconductor chip includes a first region and a second region in a horizontal direction and a first level layer, a second level layer, and a third level layer in a vertical direction.

FIG. 2 is a cross-sectional view illustrating a first bonding pad in a first region in the semiconductor package of some example embodiments, including the example embodiments of FIG. 1.

FIG. 3 is a cross-sectional view illustrating a second bonding pad in a second region in the semiconductor package of some example embodiments, including the example embodiments of FIG. 1.

FIG. 4 is a cross-sectional view illustrating a step of forming a first redistribution layer structure on a carrier as one of a plurality of steps of a method for manufacturing the semiconductor package according to some example embodiments.

FIG. 5 is a cross-sectional view illustrating a step of forming a plurality of conductive pillars on the first redistribution layer structure as one of the plurality of steps of the method for manufacturing the semiconductor package according to some example embodiments.

FIG. 6 is a cross-sectional view illustrating a step of mounting the bridge structure on the first redistribution layer structure as one of the plurality of steps of the method for manufacturing the semiconductor package according to some example embodiments.

FIG. 7 is a cross-sectional view illustrating a step of molding the plurality of conductive pillars and the bridge structure on the first redistribution layer structure with a first encapsulant as one of the plurality of steps of the method for manufacturing the semiconductor package according to some example embodiments.

FIG. 8 is a cross-sectional view illustrating a step of forming third redistribution vias and fifth redistribution vias of a second redistribution layer structure on the first encapsulant as one of the plurality of steps of the method for manufacturing the semiconductor package according to some example embodiments.

FIG. 9 is a cross-sectional view illustrating a step of forming second redistribution lines of the second redistribution layer structure as one of the plurality of steps of the method for manufacturing the semiconductor package according to some example embodiments.

FIG. 10 is a cross-sectional view illustrating a step of forming an opening at the first region of the second redistribution layer structure and forming a plurality of via holes at the second region of the second redistribution layer structure as one of the plurality of steps of the method for manufacturing the semiconductor package according to some example embodiments.

FIG. 11 is a cross-sectional view illustrating a step of forming a seed metal layer on an exposed surface of the second redistribution layer structure as one of the plurality of steps of the method for manufacturing the semiconductor package according to some example embodiments.

FIG. 12 is a cross-sectional view illustrating a step of forming a first pattern of a first photoresist by applying the first photoresist on the seed metal layer and performing a first exposure to form fourth redistribution vias, the first bonding pad, and the second bonding pad as one of the plurality of steps of the method for manufacturing the semiconductor package according to some example embodiments.

FIG. 13 is a cross-sectional view illustrating a step of performing a second exposure after the first exposure as one of the plurality of steps of the method for manufacturing the semiconductor package according to some example embodiments.

FIG. 14 is a cross-sectional view illustrating a step of forming first metal pads in the first region of the second redistribution layer structure and forming the fourth redistribution vias and second metal pads at the second region of the second redistribution layer structure as one of the plurality of steps of the method for manufacturing the semiconductor package according to some example embodiments.

FIG. 15 is a cross-sectional view illustrating a step of forming a second photoresist pattern to form a first metal layer and a second metal layer around the first metal pads of the first region and form a third metal layer and a fourth metal layer on the second metal pads of the second region as one of the plurality of steps of the method for manufacturing the semiconductor package according to some example embodiments.

FIG. 16 is a cross-sectional view illustrating a step of forming the first metal layer and the second metal layer around the first metal pads of the first region and forming the third metal layer and the fourth metal layer on the second metal pads of the second region as one of the plurality of steps of the method for manufacturing the semiconductor package according to some example embodiments.

FIG. 17 is a cross-sectional view illustrating a step of mounting the first semiconductor chip and the second semiconductor chip on the second redistribution layer structure as one of the plurality of steps of the method for manufacturing the semiconductor package according to some example embodiments.

FIG. 18 is a cross-sectional view illustrating a step of molding the first semiconductor chip and the second semiconductor chip on the second redistribution layer structure with a second encapsulant as one of the plurality of steps of the method for manufacturing the semiconductor package according to some example embodiments.

FIG. 19 is a cross-sectional view illustrating a step of de-bonding the carrier from the first redistribution layer structure and forming an external connection terminal at a lower surface of the first redistribution layer structure as one of the plurality of steps of the method for manufacturing the semiconductor package according to some example embodiments.

### DETAILED DESCRIPTION

The present inventive concepts will be described more fully hereinafter with reference to the accompanying drawings, in which some example embodiments of the inventive concepts are shown. As those skilled in the art would realize, the described example embodiments may be modified in various different ways, all without departing from the spirit or scope of the present inventive concepts.

In order to clearly describe the present inventive concepts, parts or portions that are irrelevant to the description are omitted, and identical or similar constituent elements throughout the specification are denoted by the same reference numerals.

Further, in the drawings, the size and thickness of each element are arbitrarily illustrated for ease of description, and the present inventive concepts are not necessarily limited to those illustrated in the drawings.

Throughout the specification, when a part is “connected” to another part, it includes not only a case where the part is “directly connected” but also a case where the part is “indirectly connected” with another part in between. In addition, unless explicitly described to the contrary, the word “comprise” and variations such as “comprises” or “comprising” will be understood to imply the inclusion of stated elements but not the exclusion of any other elements.

It will be understood that when an element such as a layer, film, region, area, or substrate is referred to as being “on” or “above” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

The use of the term “the” and similar demonstratives may correspond to both the singular and the plural. Operations constituting methods may be performed in any suitable order unless otherwise indicated herein or otherwise clearly contradicted by context and are not necessarily limited to the stated order.

The use of all illustrations or illustrative terms in some example embodiments is simply to describe the technical ideas in detail, and the scope of the present inventive concepts is not limited by the illustrations or illustrative terms unless they are limited by claims.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

Elements and/or properties thereof (e.g., structures, surfaces, directions, or the like) that are “substantially perpendicular”, “substantially parallel”, or “substantially coplanar” with regard to other elements and/or properties thereof will be understood to be “perpendicular”, “parallel”, or “coplanar”, respectively, with regard to the other elements and/or properties thereof within manufacturing tolerances and/or material tolerances and/or have a deviation in magnitude and/or angle from “perpendicular”, “parallel”, or “coplanar”, respectively, with regard to the other elements and/or properties thereof that is equal to or less than 10% (e.g., a. tolerance of ±10%).

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same. While the term “same,” “equal” or “identical” may be used in description of some example embodiments, it should be understood that some imprecisions may exist. Thus, when one element is referred to as being the same as another element, it should be understood that an element or a value is the same as another element within a desired manufacturing or operational tolerance range (e.g., ±10%).

It will be understood that elements and/or properties thereof described herein as being “substantially” the same and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

As described herein, when an operation is described to be performed, or an effect such as a structure is described to be established “by” or “through” performing additional operations, it will be understood that the operation may be performed and/or the effect/structure may be established “based on” the additional operations, which may include performing said additional operations alone or in combination with other further additional operations.

As described herein, an element that is described to be “spaced apart” from another element, in general and/or in a particular direction (e.g., vertically spaced apart, laterally spaced apart, etc.) and/or described to be “separated from” the other element, may be understood to be isolated from direct contact with the other element, in general and/or in the particular direction (e.g., isolated from direct contact with the other element in a vertical direction, isolated from direct contact with the other element in a lateral or horizontal direction, etc.). Similarly, elements that are described to be “spaced apart” from each other, in general and/or in a particular direction (e.g., vertically spaced apart, laterally spaced apart, etc.) and/or are described to be “separated” from each other, may be understood to be isolated from direct contact with each other, in general and/or in the particular direction (e.g., isolated from direct contact with each other in a vertical direction, isolated from direct contact with each other in a lateral or horizontal direction, etc.). Similarly, a structure described herein to be between two other structures to separate the two other structures from each other may be understood to be configured to isolate the two other structures from direct contact with each other.

Hereinafter, a semiconductor package and a method for manufacturing the semiconductor package according to some example embodiments will be described with reference to the drawings.

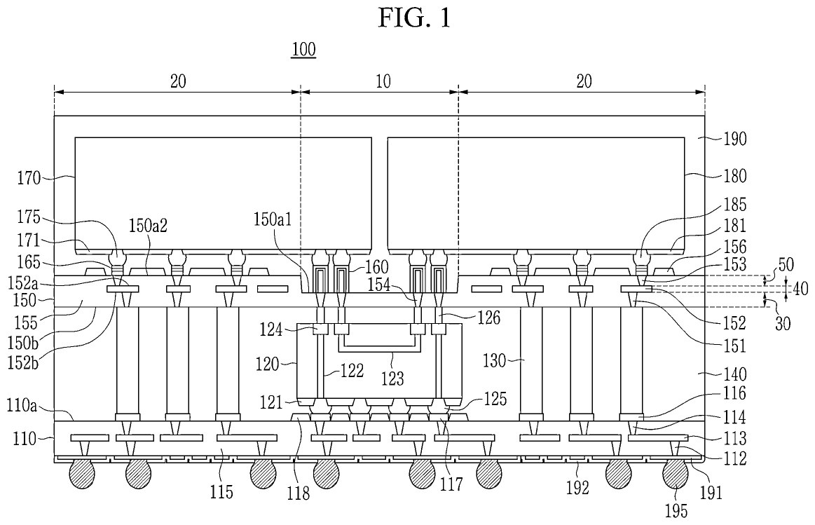

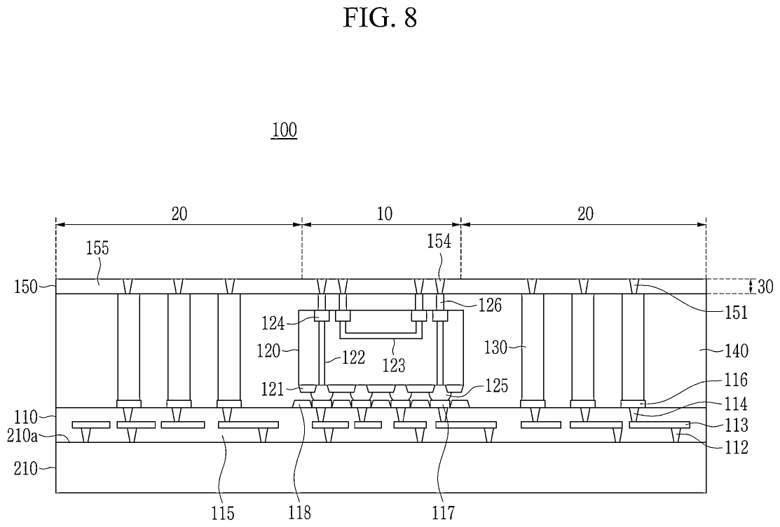

FIG. 1 a cross-sectional view illustrating the semiconductor package according to some example embodiments in which a second redistribution layer structure 150 electrically coupling a bridge structure 120 and a first semiconductor chip 170, and the bridge structure 120 and a second semiconductor chip 180 includes a first region 10 and a second region 20 in a horizontal direction and includes a first level layer 30, a second level layer 40, and a third level layer 50 in a vertical direction, where the vertical direction may be defined as extending perpendicular to a surface of one or more structures, for example extending perpendicular to an upper surface 110a of the first redistribution layer structure 110, an upper surface 210a of a carrier 210 as described with reference to at least FIG. 8, or the like, and the horizontal direction may be defined as extending parallel to the surface of the one or more structures.

As described herein, a “level” may be a distance in the vertical direction from a reference location, structure or the like. For example, a given “level” in the semiconductor package 100 may refer to a distance from the upper surface 110a of the first redistribution layer structure 110 in the vertical direction.

As shown in FIG. 1, the second redistribution layer structure 150 may define first and second regions 10 and 20, where the first region 10 may be defined as a region (e.g., portion) of the second redistribution layer structure 150 that vertically overlaps (e.g., overlaps in the vertical direction extending perpendicular to the upper surface 110a of the first redistribution layer structure 110) the bridge structure 120, and the second region 20 may be defined as a region (e.g., portion) of the second redistribution layer structure 150 that does not vertically overlap (e.g., does not overlap in the vertical direction, is exposed in the vertical direction from, etc.) the bridge structure 120. Restated, the second region 20 may be a region of the second redistribution layer structure 150 that is other than the first region 10 of the second redistribution layer structure 150 which vertically overlaps the bridge structure 120.

Referring to FIG. 1, the first region 10 includes fifth redistribution vias 154 and a second dielectric layer 155 at the first level layer 30, does not include redistribution lines and does not include any dielectric layer at the second level layer 40, and does not include redistribution vias and does not include any dielectric layer at the third level layer 50. Instead, the second level layer 40 and the third level layer 50 of the first region 10 include first bonding pads 160. As described herein, structures, elements or the like that are located within a given level layer at a given region may be referred to as being “at” the given level layer. For example, the semiconductor package 100 may include the first bonding pads 160 on the second redistribution layer structure 150 at the first region 10 of the second redistribution layer structure 150 (e.g., the first bonding pads 160 may be on the upper surface 150a1).

The second region 20 includes third redistribution vias 151 and the second dielectric layer 155 at the first level layer 30, includes second redistribution lines 152 and the second dielectric layer 155 at the second level layer 40, and includes fourth redistribution vias 153 and the second dielectric layer 155 at the third level layer 50.

The semiconductor package 100 may include a first redistribution layer structure 110, the bridge structure 120, a plurality of conductive pillars 130, a first encapsulant 140, the second redistribution layer structure 150, a plurality of first bonding pads 160, a plurality of second bonding pads 165, the first semiconductor chip 170, the second semiconductor chip 180, and a second encapsulant 190.

The first redistribution layer structure 110 may include a first dielectric layer 115, first redistribution vias 112, first redistribution lines 113, second redistribution vias 114, bonding pads 116 and 117, and an insulating layer 118. The first redistribution vias 112, the first redistribution lines 113, and the second redistribution vias 114 may be disposed within the first dielectric layer 115. In some example embodiments, a redistribution layer structure including a fewer or greater number of redistribution lines, a fewer or greater number of redistribution vias, a fewer or greater number of bonding pads, and a fewer or greater number of insulating layers is included within a scope of the present inventive concepts.

The first redistribution via 112 is disposed between the first redistribution line 113 and a bonding pad 191, and electrically couples the first redistribution line 113 and an external connection terminal 195 through the bonding pad 191 in a vertical direction. The first redistribution line 113 is disposed between the first redistribution via 112 and the second redistribution via 114, and electrically couples the first redistribution via 112 to the second redistribution via 114 in a horizontal direction. The second redistribution via 114 is disposed between the first redistribution line 113 and the bonding pads 116 and 117, and electrically couples the first redistribution line 113 and the bonding pads 116 and 117 in a vertical direction.

The bonding pad 116 is disposed between the conductive pillar 130 and the second redistribution via 114, and electrically couples the conductive pillar 130 and the second redistribution via 114. The bonding pad 117 is disposed between a connection member 125 of the bridge structure 120 and the second redistribution via 114, and electrically couples the connection member 125 and the second redistribution via 114. The insulating layer 118 functions to isolate the bonding pads 117.

The bridge structure 120 may include a plurality of through silicon vias (TSV) 122, a conductive line 123, a plurality of conductive pads 124, a plurality of insulating layers 121, a plurality of connection members 125, and a connection terminal 126. In some example embodiments, the bridge structure 120 may include a silicon bridge. The bridge structure 120 is embedded in the first encapsulant 140. The through silicon via (TSV) 122 included in the bridge structure 120 may move data quickly and vertically, and may reduce power consumption to improve performance of the semiconductor package.

The through silicon via (TSV) 122 is disposed between some of the plurality of conductive pads 124 and the connection member 125, and electrically couples the first redistribution layer structure 110 and the second redistribution layer structure 150 in a vertical direction. The conductive line 123 is disposed between other conductive pads of the plurality of conductive pads 124, and electrically couples the first semiconductor chip 170 and the second semiconductor chip 180 in a horizontal direction.

The connection terminal 126 is disposed between a conductive pad 124 and the fifth redistribution via 154 of the second redistribution layer structure 150, and electrically couples the conductive pad 124 and the fifth redistribution via 154.

The conductive pillar 130 is disposed between the first redistribution layer structure 110 and the second redistribution layer structure 150, and electrically couples the first redistribution layer structure 110 and the second redistribution layer structure 150. As shown in FIG. 1, the semiconductor package 100 may include a plurality of conductive pillars 130 on the first redistribution layer structure 110 and side by side with the bridge structure 120, such that the conductive pillars 130 and the bridge structure 120 are at least partially aligned (e.g., at least partially overlapping) with each other in a horizontal direction extending parallel or substantially parallel to an upper surface 110a of the first redistribution layer structure 110.

The first encapsulant 140 molds (e.g., covers and contacts exposed surfaces of) the bridge structure 120 and the plurality of conductive pillars 130 on the first redistribution layer structure 110.

The second redistribution layer structure 150 may include the second dielectric layer 155, and the third redistribution vias 151, the second redistribution lines 152, the fourth redistribution vias 153, and the fifth redistribution vias 154 that are within the second dielectric layer 155. In some example embodiments, a redistribution layer structure that includes a fewer or greater number of redistribution vias and a fewer or greater number of redistribution lines is included within a scope of the present inventive concepts.

The second dielectric layer 155 surrounds (e.g., horizontally surrounds, which is understood to refer to herein as surrounding in a horizontal direction extending parallel or substantially parallel to the upper surface 110a of the first redistribution layer structure 110) side surfaces of the fifth redistribution vias 154 at the first region 10, and surrounds (e.g., horizontally surrounds) the third redistribution vias 151, the second redistribution lines 152, and the fourth redistribution vias 153 at the second region 20.

The second dielectric layer 155 may be a photosensitive polymer layer. A photosensitive polymer is a material capable of forming a fine pattern by applying a photolithography process. The photosensitive polymer may include a photo imagable dielectric (PID) material. In some example embodiments, the PID may include a polyimide-based photosensitive polymer, a novolac-based photosensitive polymer, polybenzoxazole, a silicone-based polymer, an acrylate-based polymer, or an epoxy-based polymer. The PID has an advantage of relatively low material cost and ease of manufacture compared with other materials used for dielectric layers.

At the first region 10, the fifth redistribution vias 154 are surrounded (e.g., horizontally surrounded) by the second dielectric layer 155. The second dielectric layer 155 surrounding (e.g., horizontally surrounding) the side surfaces of the fifth redistribution vias 154 (e.g., the portion of the second dielectric layer 155 overlapping the fifth redistribution vias 154 in a horizontal plane extending parallel or substantially parallel to the lower surface 150b of the second redistribution layer structure 150) is defined as the first level layer 30 in the first region 10.

The fifth redistribution via 154 is disposed between the first bonding pad 160 and the connection terminal 126 of the bridge structure 120, and electrically couples the first bonding pad 160 and the connection terminal 126. One end of the fifth redistribution via 154 is directly bonded to the connection terminal 126 of the bridge structure 120, and the other end of the fifth redistribution via 154 is directly bonded to the first bonding pad 160.

At the second region 20, the third redistribution vias 151, the second redistribution lines 152, and the fourth redistribution vias 153 are surrounded (e.g., horizontally surrounded) by the second dielectric layer 155. The second dielectric layer 155 surrounding (e.g., horizontally surrounding) side surfaces of the third redistribution vias 151 (e.g., the portion of the second dielectric layer 155 overlapping and/or surrounding the third redistribution vias 151 in a horizontal plane extending parallel or substantially parallel to the lower surface 150b of the second redistribution layer structure 150) is defined as the first level layer 30, the second dielectric layer 155 surrounding (e.g., horizontally surrounding) side surfaces of the second redistribution lines 152 (e.g., the portion of the second dielectric layer 155 overlapping and/or surrounding the second redistribution lines 152 in a horizontal plane extending parallel or substantially parallel to the lower surface 150b of the second redistribution layer structure 150) is defined as the second level layer 40, and the second dielectric layer 155 surrounding side surfaces of the fourth redistribution vias 153 (e.g., the portion of the second dielectric layer 155 overlapping and/or surrounding the fourth redistribution vias 153 in a horizontal plane extending parallel or substantially parallel to the lower surface 150b of the second redistribution layer structure 150) is defined as the third level layer 50.

In some example embodiments, the first level layer 30, the second level layer 40, and the third level layer 50 may each be defined as a vertical region that extends between two separate levels (e.g., two separate distances in the vertical direction from the upper surface 110a of the first redistribution layer structure 110). For example, referring to FIG. 1, the first level layer 30 may be a region defined in the vertical direction between a lower vertical boundary defined by a level of the lower surface 150b of the second redistribution layer structure 150 and an upper vertical boundary defined by at least one of a level of an upper surface 150a1 of the second redistribution layer structure 150 in the first region 10 or a level of a lower surface 152b of one or more second redistribution lines 152. In another example, referring to FIG. 1, the second level layer 40 may be a region defined in the vertical direction between a lower vertical boundary defined by at least one of a level of an upper surface 150a1 of the second redistribution layer structure 150 in the first region 10 or a level of a lower surface 152b of one or more second redistribution lines 152 and an upper vertical boundary defined by a level of an upper surface 152a of one or more second redistribution lines 152. In another example, referring to FIG. 1, the third level layer 50 may be a region defined in the vertical direction between a lower vertical boundary defined by a level of an upper surface 152a of one or more second redistribution lines 152 and an upper vertical boundary defined by a level of an upper surface 150a2 of the second redistribution layer structure 150 in the second region 20.

The third redistribution via 151 is disposed between the second redistribution line 152 and the conductive pillar 130, and electrically couples the second redistribution line 152 and the conductive pillar 130 in a vertical direction. The second redistribution line 152 is disposed between the third redistribution via 151 and the fourth redistribution via 153, and electrically couples the third redistribution via 151 and the fourth redistribution via 153 in a horizontal direction. The fourth redistribution via 153 is disposed between the second redistribution line 152 and the second bonding pad 165, and electrically couples the second redistribution line 152 and the second bonding pad 165 in a vertical direction.

The first bonding pads 160 and the second bonding pads 165 are disposed on the second redistribution layer structure 150.

The first bonding pads 160 are disposed between the fifth redistribution via 154 and a connection member 175 of the first semiconductor chip 170 and between the fifth redistribution via 154 and a connection member 185 of the second semiconductor chip 180, and electrically couples the fifth redistribution via 154 and the first semiconductor chip 170, and the fifth redistribution via 154 and the second semiconductor chip 180. The first bonding pads 160 have a vertical thickness protruding from a lowest end of the second level layer 40 over the third level layer 50 and onto the third level layer 50.

The second bonding pad 165 is disposed between the fourth redistribution via 153 and connection members 175 and 185, and electrically couples the fourth redistribution via 153 and the connection members 175 and 185. An insulating layer 156 functions to isolate (e.g., electrically isolate) the second bonding pads 165.

The first semiconductor chip 170 is disposed on the second redistribution layer structure 150. Some connection members of the connection members 175 of the first semiconductor chip 170 are bonded to the first bonding pad 160 of the first region 10 of the second redistribution layer structure 150, and other connection members of the connection members 175 of the first semiconductor chip 170 are bonded to the second bonding pad 165 of the second region 20 of the second redistribution layer structure 150. In some example embodiments, the first semiconductor chip 170 may include a high bandwidth memory (HBM) in which a plurality of memory dies are stacked.

The second semiconductor chip 180 is disposed on the second redistribution layer structure 150. Some connection members of the connection members 185 of the second semiconductor chip 180 are bonded to the first bonding pad 160 of the first region 10 of the second redistribution layer structure 150, and other connection members 185 of the connection members of the second semiconductor chip 180 are bonded to the second bonding pad 165 of the second region 20 of the second redistribution layer structure 150. In some example embodiments, the second semiconductor chip 180 may include a central processing unit (CPU) or a graphic processing unit (GPU).

The second encapsulant 190 molds (e.g., covers and contacts exposed surfaces of) the first semiconductor chip 170, the second semiconductor chip 180, the first bonding pads 160, and the second bonding pads 165 on the second redistribution layer structure 150, and fills spaces of the second level layer 40 and the third level layer 50 of the first region 10 of the second redistribution layer structure 150 in which the dielectric layer is not formed.

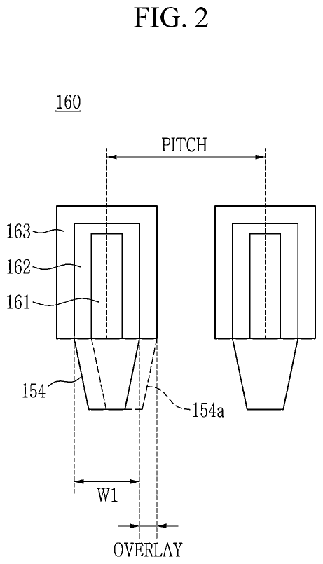

FIG. 2 is a cross-sectional view illustrating the first bonding pad 160 in the first region 10 in the semiconductor package 100 of some example embodiments, including the example embodiments of FIG. 1.

Referring to FIG. 2, the first bonding pad 160 may include a first metal pad 161, a first metal layer 162, and a second metal layer 163. In some example embodiments, the first metal pad 161 may include copper (Cu). The first metal layer 162 conformally extends along an upper surface and a side surface of the first metal pad 161, and the second metal layer 163 conformally extends along an upper surface and a side surface of the first metal layer 162.

The first metal layer 162 may include nickel (Ni). If a soldering process is performed only with the first metal pad 161 including copper, copper may diffuse and move in a direction of a solder ball so that a void is generated. Therefore, an entire upper surface and side surface of the first metal pad 161 may be covered with the first metal layer 162 including nickel so that occurrence of the void is reduced, minimized, or prevented by reducing, minimizing, or preventing the diffusion movement of copper. Accordingly, connection reliability between the bridge structure 120 and the first semiconductor chip 170, or between the bridge structure 120 and the second semiconductor chip 180 may be secured, and reliability of the semiconductor package 100 and any device including same may be improved due to improved reliability of connection (e.g., electrical connection) between the bridge structure 120 and the first semiconductor chip 170, or between the bridge structure 120 and the second semiconductor chip 180 due to reduced, minimized, or prevented occurrence of voids as described herein.

The second metal layer 163 may include gold (Au). The second metal layer 163 including gold may secure reliability, and thus improve reliability of the semiconductor package 100 and any device including same in terms of conductivity and oxidation stability.

Considering a pitch of the connection terminals 126 of the bridge structure 120 to which a fine process is applied, the first bonding pads 160 formed at the second redistribution layer structure 150 have a pitch of at least 20 μm to 50 μm (e.g., are spaced apart with a pitch therebetween of at least 20 μm to 50 μm). The pitch may be a distance in the horizontal direction between respective longitudinal central axes of one or more portions of the respective first bonding pads 160, for example a horizontal spacing distance between the respective longitudinal central axes of the respective first metal pads 161 of the adjacent first bonding pads 160 as shown for example in FIG. 2. Assuming that a width (a diameter) W1 of a typical redistribution via is 5 μm to 20 μm and an overlay of the redistribution via is 3 μm to 15 μm, in a case of forming a redistribution via 154a having an overlay at the third level layer 50 of the first region 10 of the second redistribution layer structure 150, a sum of an assumed maximum value 10 μm of a radius of the redistribution via 154a and an assumed maximum value 12.5 μm of the overlay of the redistribution via 154a is 22.5 μm. When this is applied to the neighboring redistribution vias 154a, an interval occupied by the neighboring redistribution vias 154a among a pitch 20 μm to 50 μm required between the first bonding pads 160 is 45 μm.

Thus, considering the via size, the via overlay, and the like, it is difficult to continuously form redistribution vias having the above pitch at the first level layer 30 and the third level layer 50 within the second redistribution layer structure 150, and in order to cope with this condition, there is a problem in which a high resolution photo imagable dielectric (PID) may be required and new equipment may have to be introduced.

Therefore, according to the present inventive concepts, in the first region 10 of the second redistribution layer structure 150 directly connected to the bridge structure 120, the first level layer 30 may form the fifth redistribution via 154 and the first bonding pads 160 may be disposed at the second level layer 40 and the third level layer 50 so that the above problem is solved. For example, the first bonding pads 160 may be configured to implement, and improve reliability of, electrical connection with respective fifth redistribution vias 154, even if there is an offset in the vertical overlap between a first bonding pad 160 and a fifth redistribution via 154 and/or 154a that the first bonding pad 160 is on (e.g., a horizontal offset between the respective central longitudinal axes of vertically overlapping first bonding pads 160 and fifth redistribution vias 154 and/or 154a as shown in FIG. 2), and even without use of any high resolution photo imagable dielectric (PID) and/or any new equipment to implement (e.g., create) the structures to implement the electrical connection between the bridge structure 120 and the first and/or second semiconductor chips 170 and/or 180. Thus, the reliability of the semiconductor package 100 and any device including same may be improved in the context of electrical connection reliability between the bridge structure 120 and the first and/or second semiconductor chips 170 and/or 180 without use of any high resolution photo imagable dielectric (PID) and/or any new equipment. Such improvement may be at least partially based a structure change of the second redistribution layer structure 150 such as deleting the via(s) and second dielectric layer 155 from the second and third level layers 40 and 50 of the first region 10 of the second redistribution layer structure 150 disposed just above (e.g., vertically overlapping) the bridge structure 120. Such structure change of the second redistribution layer structure 150 may thereby enable the formation of the first bonding pads 160 having a desired pitch (e.g., 20 μm to 50 μm) and having reliable electrical connection with respective fifth redistribution vias 154 having a desired pitch in the first level layer 30 of the first region 10 of the redistribution layer structure disposed just above (e.g., vertically overlapping) the bridge structure 120 without use of any high resolution photo imagable dielectric (PID) and/or any new equipment.

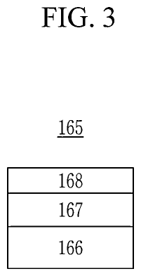

FIG. 3 is a cross-sectional view illustrating the second bonding pad 165 in the second region 20 in the semiconductor package of some example embodiments, including the example embodiments of FIG. 1.

Referring to FIG. 3, the second bonding pad 165 may include a second metal pad 166, a third metal layer 167, and a fourth metal layer 168.

In FIG. 2, the first metal layer 162 conformally extends along the upper surface and the side surface of the first metal pad 161, and the second metal layer 163 conformally extends along the upper surface and the side surface of the first metal layer 162. When FIG. 2 is compared with FIG. 3, in FIG. 3, the third metal layer 167 extends along an upper surface of the second metal pad 166, and the fourth metal layer 168 extends along an upper surface of the third metal layer 167.

In addition, contents to be described with respect to each of the second metal pad 166, the third metal layer 167, and the fourth metal layer 168 may be equally applied to contents of each of the first metal pad 161, the first metal layer 162, and the second metal layer 163 described in FIG. 2.

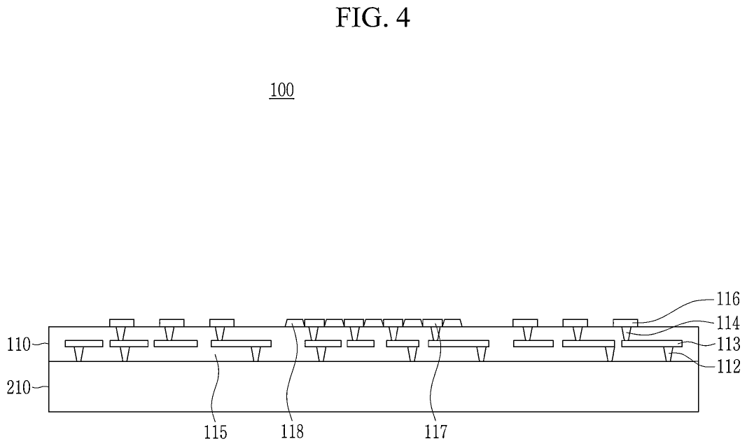

FIG. 4 is a cross-sectional view illustrating a step of forming the first redistribution layer structure 110 on a carrier 210 as one of a plurality of steps of a method for manufacturing the semiconductor package 100 according to some example embodiments.

Referring to FIG. 4, the first redistribution layer structure 110 is formed on the carrier 210. For example, the carrier 210 may include a silicon-based material such as glass or a silicon oxide, an organic material, or another material such as aluminum oxide, or a combination thereof.

A process of forming the first redistribution layer structure 110 is as follows.

First, the first dielectric layer 115 is formed on the carrier 210. In some example embodiments, the first dielectric layer 115 is formed of a polymer such as PBO, polyimide, or the like. In some example embodiments, the first dielectric layer 115 is formed of an inorganic dielectric material such as a silicon nitride, a silicon oxide, or the like. In some example embodiments, the first dielectric layer 115 may be formed by a CVD, ALD, or PECVD process.

After forming the first dielectric layer 115, via holes are formed by selectively etching the first dielectric layer 115, and the first redistribution vias 112 are formed by filling the via holes with a conductive material. Next, the first dielectric layer 115 is additionally deposited on the first redistribution vias 112 and the first dielectric layer 115, the additionally deposited first dielectric layer 115 is selectively etched to form an opening, and the opening is filled with a conductive material to form the first redistribution lines 113. Next, the first dielectric layer 115 is additionally deposited on the first redistribution lines 113 and the first dielectric layer 115, the additionally deposited first dielectric layer 115 is selectively etched to form via holes, and the second redistribution vias 114 are formed by filling the via holes with a conductive material.

In some example embodiments, the first redistribution vias 112, the first redistribution lines 113, and the second redistribution vias 114 may include at least one of: copper, aluminum, tungsten, nickel, gold, tin, titanium, or an alloy thereof. In some example embodiments, the first redistribution vias 112, the first redistribution lines 113, and the second redistribution vias 114 may be formed by performing a sputtering process. In some example embodiments, the first redistribution vias 112, the first redistribution lines 113, and the second redistribution vias 114 may be formed by performing an electroplating process after forming a seed metal layer.

Next, the insulating layer 118 may be formed on the first dielectric layer 115 of the first redistribution layer structure 110, and the bonding pads 116 and 117 may be formed on the second redistribution via 114. In some example embodiments, the insulating layer 118 may be a solder resist. The insulating layer 118 may include a plurality of openings for soldering. In some example embodiments, the bonding pads 116 and 117 may include at least one of: copper, nickel, zinc, gold, silver, platinum, palladium, chromium, titanium, or an alloy thereof.

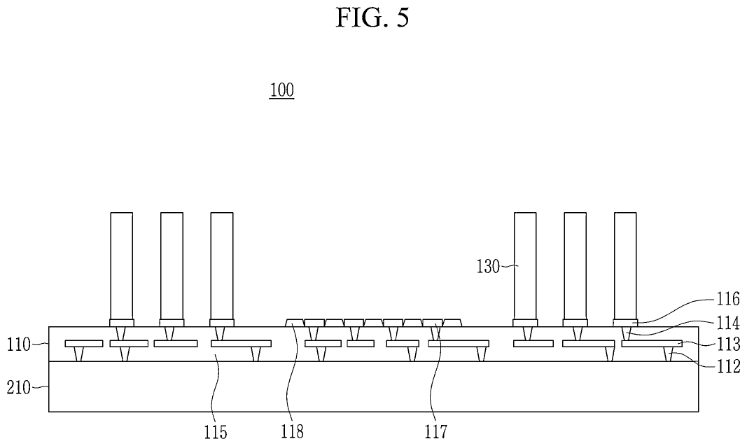

FIG. 5 is a cross-sectional view illustrating a step of forming the plurality of conductive pillars 130 on the first redistribution layer structure 110 as one of the plurality of steps of the method for manufacturing the semiconductor package 100 according to some example embodiments.

Referring to FIG. 5, the conductive pillars 130 are bonded to the bonding pads 116 of the first redistribution layer structure 110 to be formed in a vertical direction. In some example embodiments, the conductive pillars 130 may be formed by performing a sputtering process. In some example embodiments, the conductive pillars 130 may be formed by performing an electroplating plating process after forming a seed metal layer. In some example embodiments, the conductive pillar 130 may include at least one of: copper (Cu), nickel (Ni), gold (Au), silver (Ag), aluminum (Al), tungsten (W), titanium (Ti), tantalum (Ta), indium (In), molybdenum (Mo), manganese (Mn), cobalt (Co), tin (Sn), magnesium (Mg), rhenium (Re), beryllium (Be), gallium (Ga), ruthenium (Ru), or an alloy thereof.

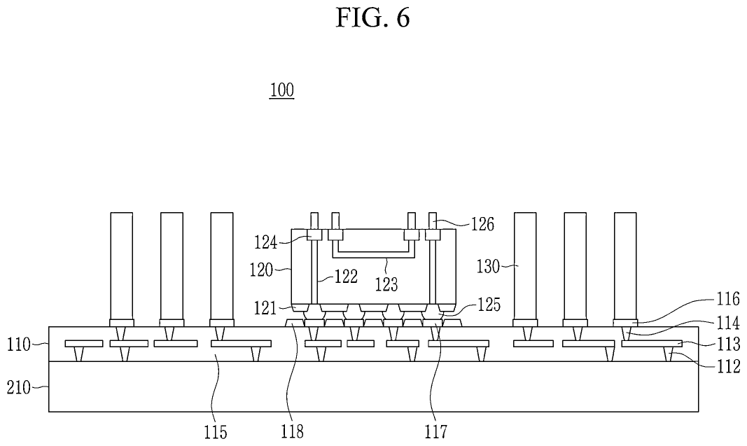

FIG. 6 is a cross-sectional view illustrating a step of mounting the bridge structure 120 on the first redistribution layer structure 110 as one of the plurality of steps of the method for manufacturing the semiconductor package 100 according to some example embodiments.

Referring to FIG. 6, the bridge structure 120 is mounted on the first redistribution layer structure 110. The connection member 125 of the bridge structure 120 may be bonded to the bonding pad 117 of the first redistribution layer structure 110 by performing a soldering process.

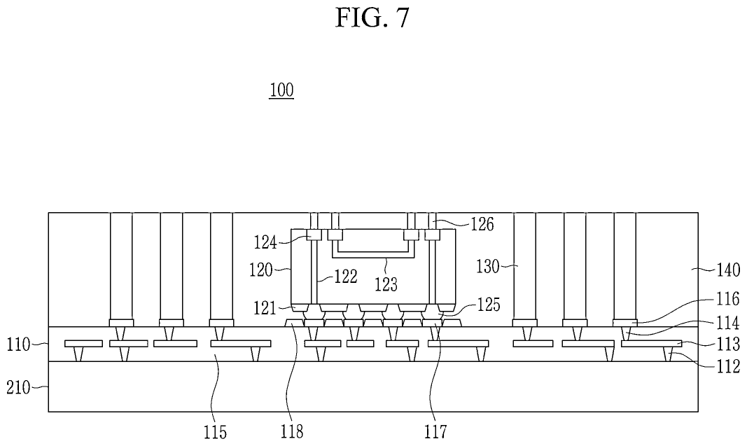

FIG. 7 is a cross-sectional view illustrating a step of molding the plurality of conductive pillars 130 and the bridge structure 120 on the first redistribution layer structure 110 with the first encapsulant 140 as one of the plurality of steps of the method for manufacturing the semiconductor package 100 according to some example embodiments.

Referring to FIG. 7, the conductive pillars 130 and the bridge structure 120 are molded on the first redistribution layer structure 110 with the first encapsulant 140. In some example embodiments, the first encapsulant 140 may be formed of a thermosetting resin such as an epoxy resin. In some example embodiments, the first encapsulant 140 may be formed of a film (e.g., Ajinomoto Build-up Film (ABF)) in which a reinforcing material such as an inorganic filler is uniformly dispersed in an epoxy resin. In some example embodiments, the first encapsulant 140 may be an epoxy molding compound (EMC).

A process of molding with the first encapsulant 140 may include a compression molding or transfer molding process. After molding is performed with the first encapsulant 140, a CMP process may be performed at an upper surface of the first encapsulant 140 so that an upper surface of the conductive pillars 130 and an upper surface of the connection terminal 126 are exposed.

FIG. 8 is a cross-sectional view illustrating a step of forming the third redistribution vias 151 and the fifth redistribution vias 154 of the second redistribution layer structure 150 on the first encapsulant 140 as one of the plurality of steps of the method for manufacturing the semiconductor package according to some example embodiments.

Referring to FIG. 8, the second dielectric layer 155 is formed at the first level layer 30 of the second redistribution layer structure 150 on the first encapsulant 140. In some example embodiments, the second dielectric layer 155 is formed of a polymer such as PBO, polyimide, or the like. In some example embodiments, the second dielectric layer 155 is formed of an inorganic dielectric material such as a silicon nitride, a silicon oxide, or the like. In some example embodiments, the second dielectric layer 155 may be formed by a CVD, ALD, or PECVD process.

After the second dielectric layer 155 is formed, the second dielectric layer 155 is selectively etched to form via-holes and a conductive material is filled in the via-holes, so that in the first level layer 30, the third redistribution vias 151 are formed at the second region 20 while forming the fifth redistribution vias 154 at the first region 10.

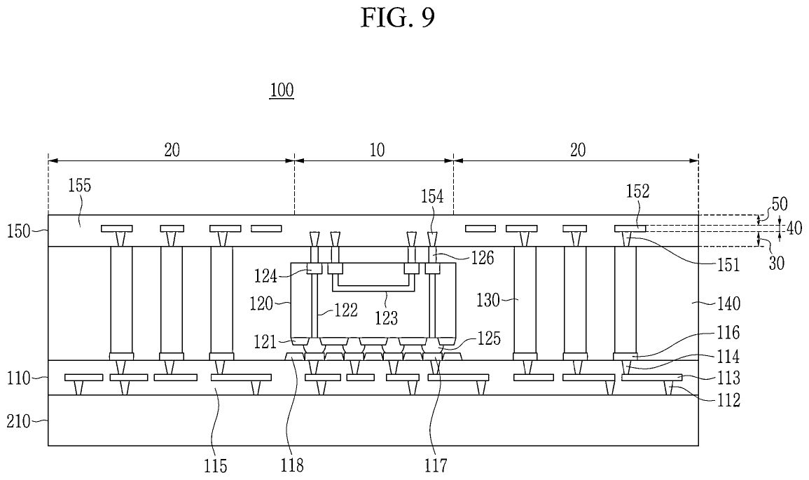

FIG. 9 is a cross-sectional view illustrating a step of forming the second redistribution lines 152 of the second redistribution layer structure 150 as one of the plurality of steps of the method for manufacturing the semiconductor package 100 according to some example embodiments.

Referring to FIG. 9, the second dielectric layer 155 of the second level layer 40 is additionally deposited on the third redistribution vias 151, the fifth redistribution vias 154, and the second dielectric layer 155 of the first level layer 30. Next, in the second region 20, an opening is formed by selectively etching the additionally deposited second dielectric layer 155, and the second redistribution lines 152 are formed by filling the opening with a conductive material. Next, the second dielectric layer 155 of the third level layer 50 is additionally deposited on the second redistribution lines 152 and the additionally deposited second dielectric layer 155 of the second level layer 40.

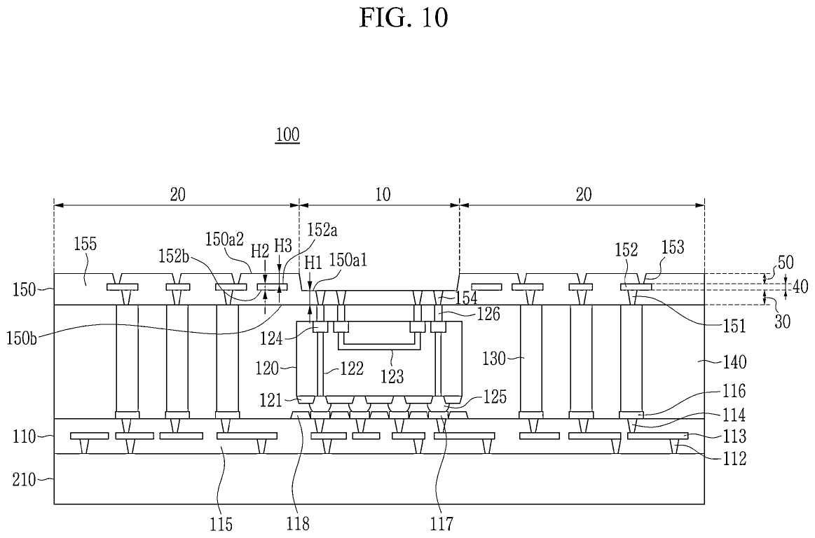

FIG. 10 is a cross-sectional view illustrating a step of forming an opening at the first region 10 of the second redistribution layer structure 150 and forming a plurality of via holes at the second region 20 of the second redistribution layer structure as one of the plurality of steps of the method for manufacturing the semiconductor package 100 according to some example embodiments.

Referring to FIG. 10, while forming the opening at the first regions 10 of the second level layer 40 and the third level layer 50 of the second redistribution layer structure 150, the via holes are formed by selectively etching the second dielectric layer 155 at the second region 20 of the third level layer 50 of the second redistribution layer structure 150. The opening and the via-holes are formed through photoresist deposition, photomask deposition, exposure, development, and etching.

According to the present inventive concepts, as an entire opening is formed without forming vias at the second level layer 40 and the third level layer 50 of the first region 10 of the second redistribution layer structure 150, a residue generated when a photoresist pattern is formed to form vias having a fine pitch is not generated. As a result, the reliability of the resultant semiconductor package 100 and any device including same may be improved, based on omitting at least a portion of the photoresist pattern at the first region 10 of the second redistribution layer structure 150 vertically overlapping the bridge structure 120 (e.g., based on omitting the second dielectric layer 155 at the first region 10 of the second and third level layers 40 and 50) and thus preventing residue generated from the photoresist pattern at the first region 10 of the second redistribution layer structure 150 based on preventing the formation of any small-sized vias therein.

Since a vertical thickness H3 of the third level layer 50 at the second region 20 of the second redistribution layer structure 150 (e.g., a vertical thickness H3 between an upper surface 152a of one or more second redistribution lines 152 and an upper surface 150a2 of the second redistribution layer structure 150 in the second region 20) is smaller than a vertical thickness H1 of the first level layer 30 (e.g., a vertical thickness H1 between a lower surface 150b of the second redistribution layer structure 150 and a lower surface 152b of one or more second redistribution lines 152), sizes of the fourth redistribution vias 153 formed at the third level layer 50 are reduced compared to sizes of the third redistribution vias 151. In some example embodiments, the vertical thickness H1 of the first level layer 30 may be about 5 μm to 10 μm. In some example embodiments, a vertical thickness H2 of the second level layer 40 (e.g., a vertical thickness H2 between a lower surface 152b of one or more second redistribution lines 152 and an upper surface 152a of one or more second redistribution lines 152) may be about 2 μm to 5 μm. In some example embodiments, the vertical thickness H3 of the third level layer 50 may be about 3 μm to 5 μm.

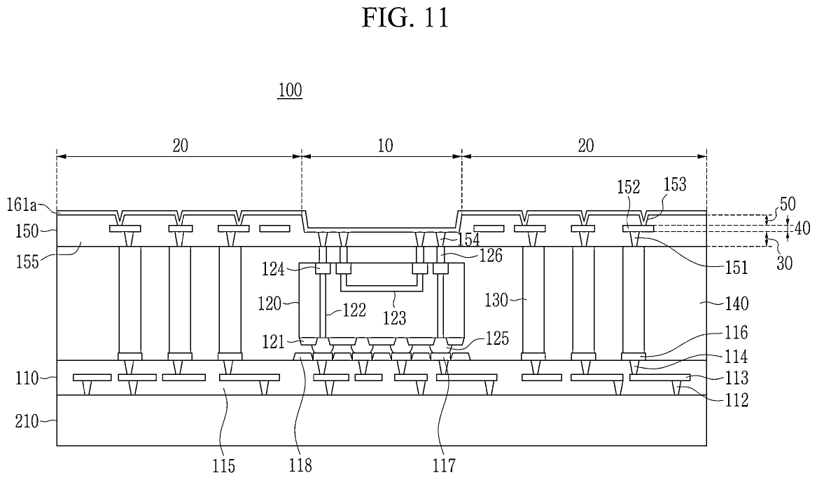

FIG. 11 is a cross-sectional view illustrating a step of forming a seed metal layer 161a on an exposed surface of the second redistribution layer structure 150 as one of the plurality of steps of the method for manufacturing the semiconductor package 100 according to some example embodiments.

Referring to FIG. 11, the seed metal layer 161a is formed on the exposed surface, the opening, and the via-holes of the second redistribution layer structure 150. In some example embodiments, the seed metal layer 161a may include at least one of: copper, aluminum, titanium, palladium, silver, or gold. In some example embodiments, the seed metal layer 161a is formed by electroless plating. In some example embodiments, a cleaning process or a metal catalyst activation pretreatment process may be performed prior to the electroless plating. In some example embodiments, a planarization (CMP) process for a post process may be performed after the electroless plating. In some example embodiments, the seed metal layer 161a is formed by sputtering.

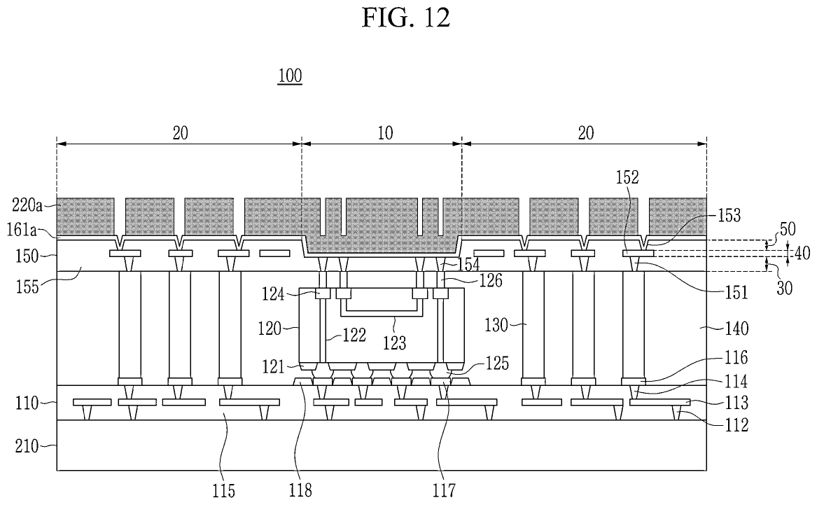

FIG. 12 is a cross-sectional view illustrating a step of forming a first pattern 220a of a first photoresist by applying the first photoresist on the seed metal layer 161a and performing a first exposure to form the fourth redistribution vias 153, the first bonding pad 160, and the second bonding pad 165 as one of the plurality of steps of the method for manufacturing the semiconductor package 100 according to some example embodiments.

Referring to FIG. 12, first, the first photoresist is applied on the seed metal layer 161a. At the first region 10, the first photoresist is formed on the seed metal layer 161a through the second level layer 40 and the third level layer 50 to on the third level layer 50, and at the second region 20, the first photoresist is formed on the seed metal layer 161a. Next, since a via hole is formed at the third level layer 50 of the second region 20 of the second redistribution layer structure 150, the first exposure is performed by focusing on an uppermost portion (or an uppermost surface of the second dielectric layer 155) of the third level layer 50.

After the first exposure is performed, the first photoresist of the first region 10 is developed only to a height equal to a height of the uppermost portion of the third level layer 50, and a portion less than or equal to the uppermost height of the third level layer 50 is not developed. In addition, in the first region 10, since the seed metal layer 161a is disposed below the uppermost portion of the third level layer 50 where the first exposure is focused, the first pattern 220a of the first photoresist is not formed up to the seed metal layer 161a so that the seed metal layer 161a is not exposed. The first photoresist of the second region 20 is developed to a height equal to the uppermost height of the third level layer 50. Since a via hole is formed at the third level layer 50 of the second region 20 of the second redistribution layer structure 150, the seed metal layer 161a underneath the first photoresist is exposed.

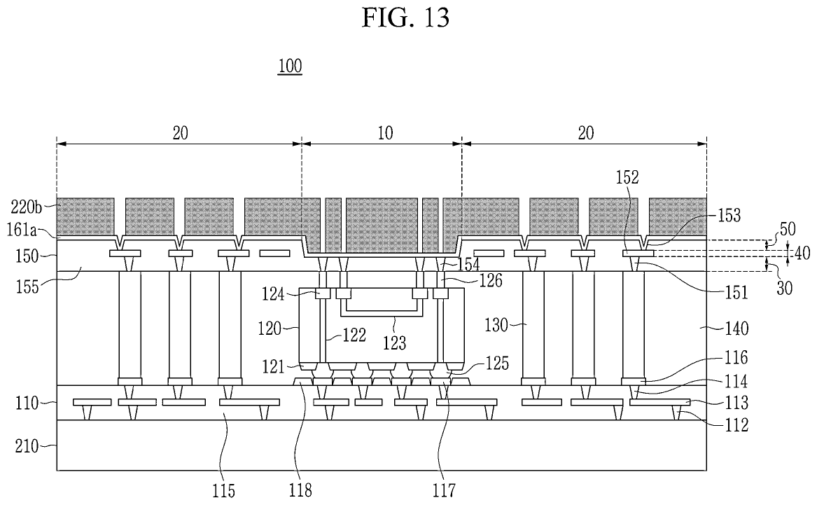

FIG. 13 is a cross-sectional view illustrating a step of performing a second exposure after the first exposure as one of the plurality of steps of the method for manufacturing the semiconductor package 100 according to some example embodiments.

Referring to FIG. 13, in the first region 10, the second exposure is performed by focusing on an uppermost portion (or uppermost surfaces of the fifth redistribution vias) of the first level layer 30.

After the second exposure is performed, in the first region 10, a portion from an uppermost portion of the first level layer 30 of the first photoresist that is not developed during the first exposure to an uppermost portion of the third level layer 50 is additionally developed and a second pattern 220b of the first photoresist is formed up to the seed metal layer 161a so that the seed metal layer 161a underneath the first photoresist is exposed.

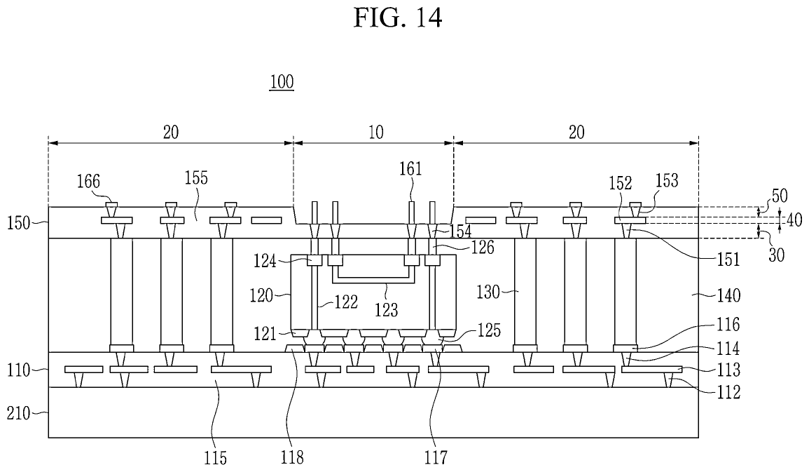

FIG. 14 is a cross-sectional view illustrating a step of forming first metal pads 161 in the first region 10 of the second redistribution layer structure 150 and forming the fourth redistribution vias 153 and second metal pads 166 at the second region 20 of the second redistribution layer structure as one of the plurality of steps of the method for manufacturing the semiconductor package 100 according to some example embodiments.

Referring to FIG. 14, the first metal pads 161 are formed at the first region 10 of the second redistribution layer structure 150, and the fourth redistribution vias 153 and the second metal pads 166 are formed at the second region 20. The first metal pads 161 of the first region 10 and the fourth redistribution vias 153 and the second metal pads 166 of the second region 20 are formed by growing a metal film by electroplating from the seed metal layer 161a. In some example embodiments, after the first metal pads 161 of the first region 10 and the fourth redistribution vias 153 and the second metal pads 166 of the second region 20 are formed, an annealing process may be performed. In some example embodiments, the first metal pads 161 of the first region 10 and the fourth redistribution vias 153 and the second metal pads 166 of the second region 20 may include at least one of: copper, aluminum, titanium, palladium, silver, or gold.

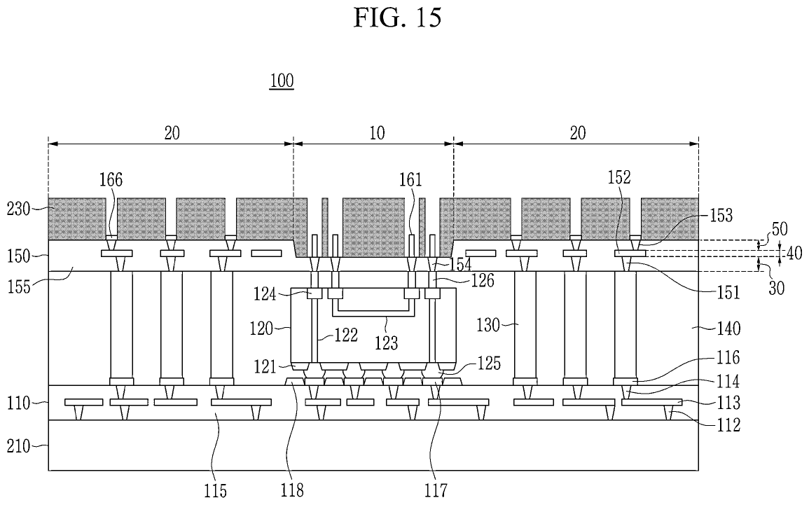

FIG. 15 is a cross-sectional view illustrating a step of forming a second photoresist pattern to form the first metal layer 162 and the second metal layer 163 around the first metal pads 161 of the first region 10 and form the third metal layer 167 and the fourth metal layer 168 on the second metal pads 166 of the second region 20 as one of the plurality of steps of the method for manufacturing the semiconductor package 100 according to some example embodiments.

Referring to FIG. 15, the second photoresist pattern 230 is formed on the second redistribution layer structure 150. The second photoresist pattern 230 is formed through processes of photoresist application, photomask deposition, exposure, and development. An opening within the second photoresist pattern 230 at the first region 10 has a width greater than that of the first metal pad 161, and an upper surface of the second dielectric layer 155 is exposed from a lower surface of the opening. An opening within the second photoresist pattern 230 at the second region 20 has the same width as that of the second metal pad 166.

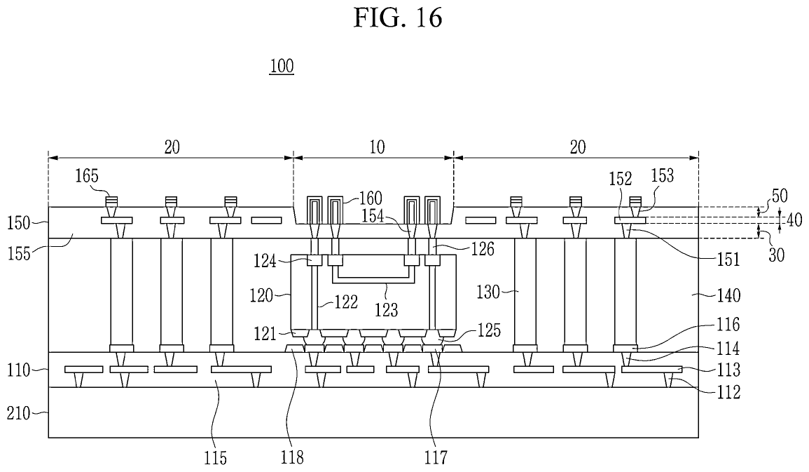

FIG. 16 is a cross-sectional view illustrating a step of forming the first metal layer 162 and the second metal layer 163 around the first metal pads 161 of the first region 10 and forming the third metal layer 167 and the fourth metal layer 168 on the second metal pads 166 of the second region 20 as one of the plurality of steps of the method for manufacturing the semiconductor package 100 according to some example embodiments.

Referring to FIG. 16, the first metal layer 162 and the second metal layer 163 are formed around the first metal pad 161 at the first region 10. By plating, the first metal layer 162 is conformally extended along an upper surface and a side surface of the first metal pad 161, and the second metal layer 163 is conformally extended along an upper surface and a side surface of the first metal layer 162.

The third metal layer 167 and the fourth metal layer 168 are formed on the second metal pad 166 in the second region 20. By plating, the third metal layer 167 is formed to extend along an upper surface of the second metal pad 166, and the fourth metal layer 168 is formed to extend along an upper surface of the third metal layer 167.

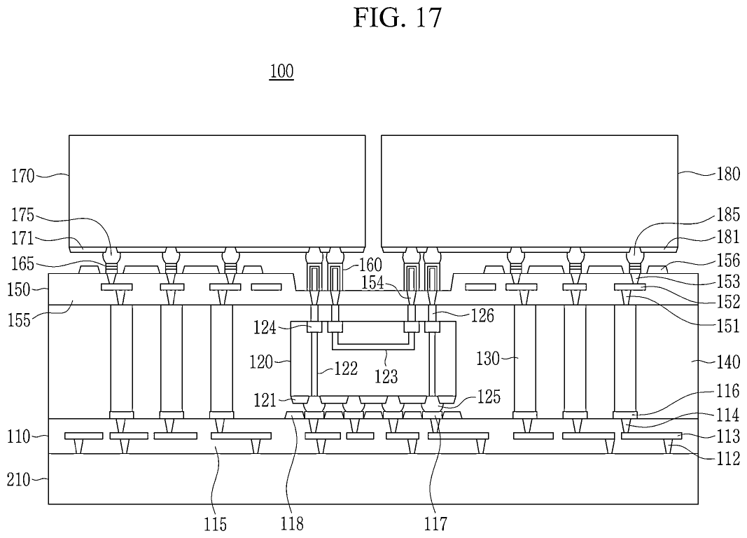

FIG. 17 is a cross-sectional view illustrating a step of mounting the first semiconductor chip 170 and the second semiconductor chip 180 on the second redistribution layer structure 150 as one of the plurality of steps of the method for manufacturing the semiconductor package 100 according to some example embodiments.

Referring to FIG. 17, the first semiconductor chip 170 and the second semiconductor chip 180 are mounted above the second redistribution layer structure 150. The first semiconductor chip 170 is bonded to the first bonding pads 160 and the second bonding pads 165 disposed on an upper surface of the second redistribution layer structure 150 by the connection member 175 formed at a lower surface of the first semiconductor chip 170 at gaps in an insulating layer 171 on the lower surface of the first semiconductor chip 170, such that the insulating layer 171 isolates the connection members 175 from each other. In some example embodiments, the insulating layer 171 may be a solder resist. The second semiconductor chip 180 is bonded to the first bonding pads 160 and the second bonding pads 165 disposed on the upper surface of the second redistribution layer structure 150 by the connection member 185 formed at a lower surface of the second semiconductor chip 180 at gaps in an insulating layer 181 on the lower surface of the second semiconductor chip 180, such that the insulating layer 181 isolates the connection members 185 from each other. In some example embodiments, the insulating layer 181 may be a solder resist.

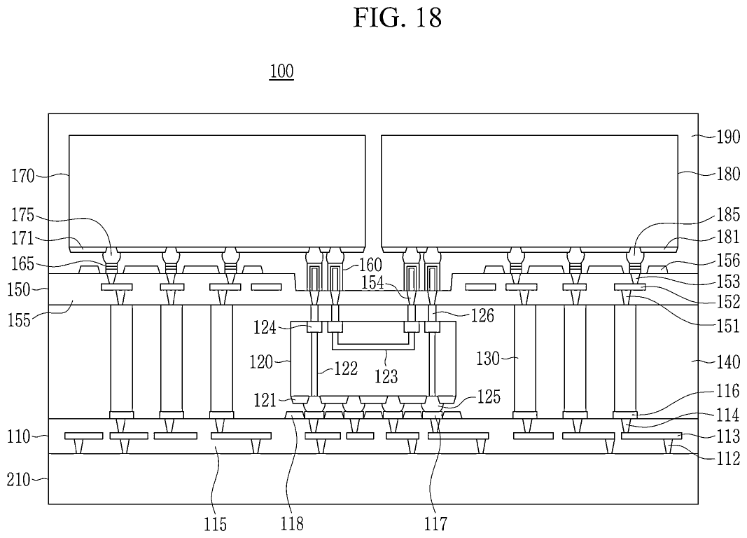

FIG. 18 is a cross-sectional view illustrating a step of molding the first semiconductor chip 170 and the second semiconductor chip 180 on the second redistribution layer structure 150 with a second encapsulant 190 as one of the plurality of steps of the method for manufacturing the semiconductor package 100 according to some example embodiments.

Referring to FIG. 18, the first semiconductor chip 170 and the second semiconductor chip 180 are molded on the second redistribution layer structure 150 with the second encapsulant 190. In an example, a process of molding with the second encapsulant 190 may include a compression molding or transfer molding process. After molding is performed with the second encapsulant 190, a CMP process may be performed at an upper surface of the second encapsulant 190.

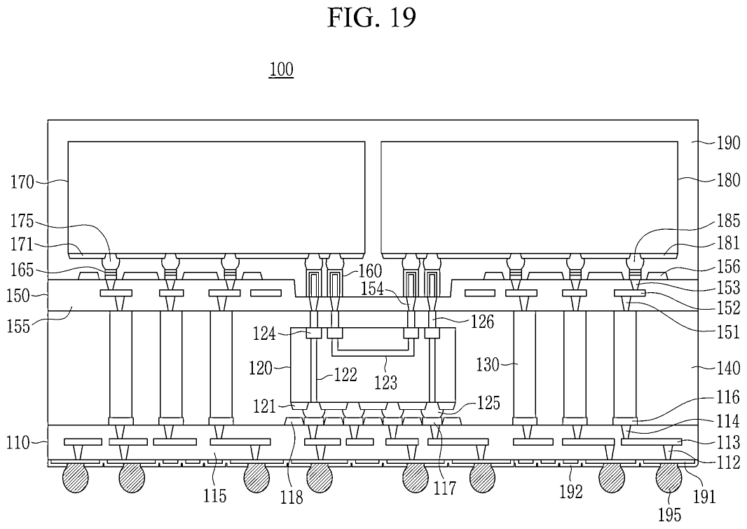

FIG. 19 is a cross-sectional view illustrating a step of de-bonding (or removing) the carrier 210 from the first redistribution layer structure 110 and forming the external connection terminal 195 at a lower surface of the first redistribution layer structure 110 as one of the steps of the method for manufacturing the semiconductor package 100 according to some example embodiments.

Referring to FIG. 19, the carrier 210 is de-bonded from the first redistribution layer structure 110, and the bonding pad 191, the insulating layer 192, and the external connection terminal 195 are formed below the lower surface of the first redistribution layer structure 110. In some example embodiments, the external connection terminal 195 may include at least one of: tin (Sn), silver (Ag), lead, nickel, copper (Cu), or an alloy thereof.

While this inventive concepts have been described in connection with what is presently considered to be practical example embodiments, it is to be understood that the inventive concepts are not limited to such example embodiments, but, on the contrary, the inventive concepts are intended to cover various modifications and equivalent arrangements included within the spirit and scope of the appended claims.

What is claimed is:

1. A semiconductor package, comprising:
a first redistribution layer structure;
a bridge structure on the first redistribution layer structure;
a plurality of conductive pillars on the first redistribution layer structure and side by side with the bridge structure;
an encapsulant molding the bridge structure and the plurality of conductive pillars on the first redistribution layer structure;
a second redistribution layer structure on the encapsulant, wherein a region of the second redistribution layer structure vertically overlapping the bridge structure is defined as a first region and a region other than the first region is defined as a second region; and
a plurality of bonding pads on the second redistribution layer structure at the first region,
wherein a vertical thickness of the first region is smaller than a vertical thickness of the second region.

2. The semiconductor package of claim 1, wherein the second redistribution layer structure includes a plurality of first vias at the first region, and one end of each first via of the plurality of first vias is directly bonded to the bridge structure and another end of each first via of the plurality of first vias is directly bonded to each of the plurality of bonding pads.

3. The semiconductor package of claim 1, wherein adjacent bonding pads of the plurality of bonding pads have a pitch of 20 μm to 50 μm.

4. The semiconductor package of claim 1, wherein the bridge structure includes a silicon bridge.

5. The semiconductor package of claim 1, wherein the bridge structure includes a through silicon via (TSV).

6. A semiconductor package, comprising:
a first redistribution layer structure;
a bridge structure on the first redistribution layer structure;
a plurality of conductive pillars on the first redistribution layer structure and side by side with the bridge structure;
a first encapsulant molding the bridge structure and the plurality of conductive pillars on the first redistribution layer structure;
a second redistribution layer structure on the first encapsulant, wherein a region of the second redistribution layer structure vertically overlapping the bridge structure is defined as a first region and a region other than the first region is defined as a second region; and
a plurality of first bonding pads on the first region;
a plurality of second bonding pads on the second region;
a first semiconductor chip and a second semiconductor chip on the plurality of first bonding pads and the plurality of second bonding pads; and
a second encapsulant molding the plurality of first bonding pads, the plurality of second bonding pads, the first semiconductor chip, and the second semiconductor chip on the second redistribution layer structure,
wherein a vertical thickness of the first region is smaller than a vertical thickness of the second region.

7. The semiconductor package of claim 6, wherein the second redistribution layer structure includes a plurality of first vias at the first region, and the second redistribution layer structure includes a plurality of second vias, a plurality of redistribution lines, and a plurality of third vias at the second region.

8. The semiconductor package of claim 7, wherein the second redistribution layer structure further includes a dielectric layer, a region of the dielectric layer surrounding side surfaces of the plurality of first vias and the plurality of second vias is defined as a first level layer, a region of the dielectric layer surrounding side surfaces of the plurality of redistribution lines is defined as a second level layer, and a region of the dielectric layer surrounding side surfaces of the plurality of third vias is defined as a third level layer.

9. The semiconductor package of claim 8, wherein the dielectric layer includes a photo imagable dielectric (PID).

10. The semiconductor package of claim 8, wherein a vertical thickness of the first level layer is greater than a vertical thickness of the third level layer.

11. The semiconductor package of claim 6, wherein each first bonding pad of the plurality of first bonding pads comprises:
a metal pad;
a first metal layer conformally extending along an upper surface and a side surface of the metal pad; and
a second metal layer conformally extending along an upper surface and a side surface of the first metal layer.

12. The semiconductor package of claim 11, wherein the metal pad includes copper (Cu), the first metal layer includes nickel (Ni), and the second metal layer includes gold (Au).

13. The semiconductor package of claim 6, wherein each second bonding pad of the plurality of second bonding pads comprises:
a metal pad;
a first metal layer on an upper surface of the metal pad; and
a second metal layer on an upper surface of the first metal layer.

14. A method for manufacturing a semiconductor package, the method comprising:
mounting a bridge structure on a first redistribution layer structure and forming a plurality of conductive pillars on the first redistribution layer structure;
molding the bridge structure and the plurality of conductive pillars with an encapsulant; and
forming a second redistribution layer structure on the encapsulant, wherein a region of the second redistribution layer structure vertically overlapping the bridge structure is defined as a first region and a region other than the first region is defined as a second region, and a vertical thickness of the first region is smaller than a vertical thickness of the second region.

15. The method of claim 14, wherein the step of forming the second redistribution layer structure on the encapsulant comprises:
forming a first dielectric layer on the bridge structure;
forming a plurality of first vias within the first dielectric layer at the first region and simultaneously forming a plurality of second vias within the first dielectric layer at the second region;
forming a second dielectric layer on the plurality of first vias, the plurality of second vias, and the first dielectric layer;
forming a plurality of redistribution lines within the second dielectric layer at the second region;
forming a third dielectric layer on the plurality of redistribution lines and the second dielectric layer;
forming an opening at the first region to expose upper surfaces of the plurality of first vias and simultaneously forming a plurality of third via holes within the third dielectric layer at the second region; and
forming a plurality of first metal pads at the first region and simultaneously forming a plurality of third vias and a plurality of second metal pads at the second region.

16. The method of claim 15, further comprising forming a metal seed layer on the opening of the first region and the plurality of third via holes of the second region after the step of forming of the opening at the first region to expose the upper surfaces of the plurality of first vias and the simultaneously forming of the plurality of third via holes within the third dielectric layer at the second region.

17. The method of claim 16, wherein the step of forming the plurality of first metal pads at the first region and the simultaneously forming of the plurality of third vias and the plurality of second metal pads at the second region are performed based on electroplating.

18. The method of claim 15, further comprising forming a photoresist pattern for forming the plurality of first metal pads, the plurality of third vias, and the plurality of second metal pads before the step of forming the plurality of first metal pads at the first region and the simultaneously forming of the plurality of third vias and the plurality of second metal pads at the second region.

19. The method of claim 18, wherein the step of forming the photoresist pattern comprises:
performing a first exposure for the first region and the second region based on focusing on an uppermost surface of the third dielectric layer; and
performing a second exposure for the first region based on focusing on uppermost surfaces of the plurality of first vias.

20. The method of claim 15, further comprising forming one or more metal layers around each first metal pad of the plurality of first metal pads and on each second metal pad of the plurality of second metal pads after the step of forming the plurality of first metal pads at the first region and the simultaneously forming of the plurality of third vias and the plurality of second metal pads at the second region.
